(19) United States
(12) Patent Application Publication
(10) Pub. No.: US 2008/0159153 A1
(43) Pub. Date: Jul. 3, 2008

(54) METHOD AND APPARATUS FOR AUTOMATIC TROUBLE ISOLATION FOR DIGITAL SUBSCRIBER LINE ACCESS MULTIPLEXER

(76) Inventors: Paritosh Bajpay, Edison, NJ (US); Monowar Hossain, Middletown, NJ (US); Michael Lambert, Springtown, TX (US); Scott Taylor, Frisco, TX (US); Chen-Yui Yang, Marlboro, NJ (US)

Correspondence Address: AT&T CORP., ROOM 2A207, ONE AT&T WAY, BEDMINSTER, NJ, 07921, US

(21) Appl. No.: 11/618,908

(22) Filed: Dec. 31, 2006

(51) Int. Cl. G01R 31/08

(52) U.S. Cl. 370/242

(57) ABSTRACT

A method and apparatus for performing automatic trouble isolation for a Digital Subscriber Line Access Multiplexer (DSLAM) used on packet networks are disclosed.

The present invention relates generally to communication networks and, more particularly, to a method and apparatus for automatic trouble isolation for a digital subscriber line access multiplexer used on packet networks, e.g. Internet Protocol (IP) networks.

### BACKGROUND OF THE INVENTION

Since Internet services are becoming ubiquitous, more and more businesses and consumers are relying on their Internet connections for both voice and data transport needs. For example, customers may access the Internet through a local area network, a cable network, a digital subscriber line, etc. A digital subscriber line is a type of high-speed connection provided over the same wires as the regular telephone lines. A network service provider aggregates multiple digital subscriber lines on to a single Asynchronous Transfer Mode (ATM) or Frame Relay (FR) line using a Digital Subscriber Line Access Multiplexer (DSLAM). When degradation or a failure is detected for a DSL service, trouble isolation is performed by having maintenance personnel check devices from end-to-end. Performing such trouble isolation one-by-one is possible for a small number of customers with few trouble reports. However, the number of subscribers for DSL service and the number of trouble reports are very large and ever increasing with the growth of the Internet.

Therefore, there is a need for a method that provides automatic trouble isolation for digital subscriber line access multiplexers.

### SUMMARY OF THE INVENTION

In one embodiment, the present invention discloses a method and apparatus for performing automatic trouble isolation for a digital subscriber line access multiplexer used on packet networks. The method receives a request or a ticket for trouble isolation associated with a Digital Subscriber Line (DSL) service. The method then performs connectivity test to customer premise equipment to differentiate between failures in the customer premise versus the network. If the trouble is not due to customer premise equipment, the method then performs connectivity test to an ATM or FR switch used for the DSL service in order to differentiate between failures in DSLAM versus ATM/FR switch network. If the failure is not due to the ATM/FR switch, the method then performs tests on the DSLAM. The method performs tests designed for isolating various types of failure on the DSLAM. For example, connectivity tests, logical tests for isolating software and configuration failures, and tests designed to isolate specific types of physical failures.

### BRIEF DESCRIPTION OF THE DRAWINGS

The teaching of the present invention can be readily understood by considering the following detailed description in conjunction with the accompanying drawings, in which:

FIG. 1 illustrates an exemplary network related to the present invention;

FIG. 2 illustrates an exemplary network with automatic trouble isolation of DSLAM;

FIG. 3 illustrates a flowchart of a method for automatic trouble isolation of DSLAM; and

FIG. 4 illustrates a high-level block diagram of a general-purpose computer suitable for use in performing the functions described herein.

To facilitate understanding, identical reference numerals have been used, where possible, to designate identical elements that are common to the figures.

### DETAILED DESCRIPTION

The present invention broadly discloses a method and apparatus for performing automatic trouble isolation for a digital subscriber line access multiplexer used on packet networks. Although the present invention is discussed below in the context of IP networks, the present invention is not so limited. Namely, the present invention can be applied for other networks, e.g. Public Switched Telephone Network (PSTN).

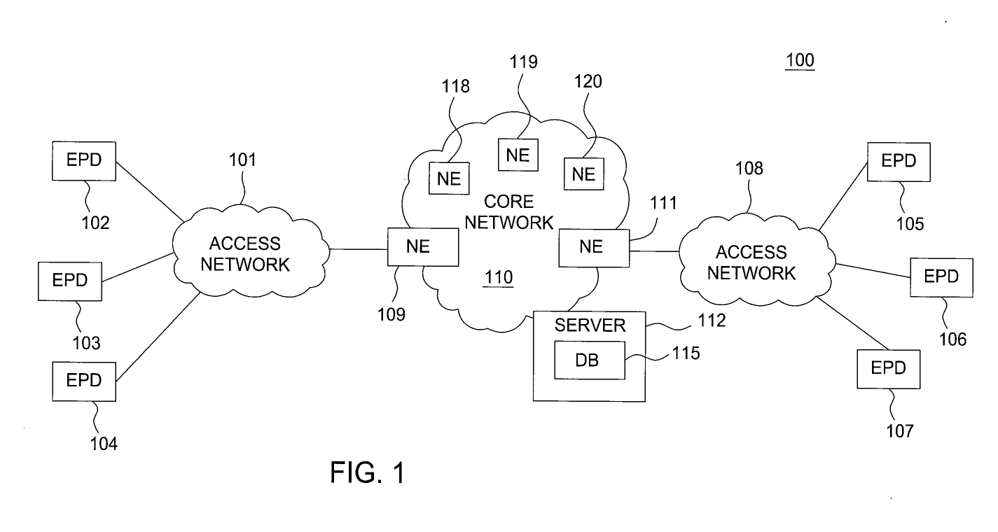

FIG. 1 is a block diagram depicting an exemplary packet network 100 related to the current invention. Exemplary packet networks include Internet protocol (IP) networks, Asynchronous Transfer Mode (ATM) networks, frame-relay networks, and the like. An IP network is broadly defined as a network that uses Internet Protocol such as IPv4 or IPv6 to exchange data packets.

In one embodiment, the packet network may comprise a plurality of endpoint devices 102-104 configured for communication with the core packet network 110 (e.g., an IP based core backbone network supported by a service provider) via an access network 101. Similarly, a plurality of endpoint devices 105-107 are configured for communication with the core packet network 110 via an access network 108. The network elements 109 and 111 may serve as gateway servers or edge routers for the network 110. Those skilled in the art will realize that although only six endpoint devices, two access networks, and four network elements (NEs) are depicted in FIG. 1, the communication system 100 may be expanded by including additional endpoint devices, access networks, and border elements without altering the present invention.

The endpoint devices 102-107 may comprise customer endpoint devices such as personal computers, laptop computers, Personal Digital Assistants (PDAs), servers, and the like. The access networks 101 and 108 serve as a means to establish a connection between the endpoint devices 102-107 and the NEs 109 and 111 of the core network 110. The access networks 101, 108 may each comprise a Digital Subscriber Line (DSL) network, a broadband cable access network, a Local Area Network (LAN), a Wireless Access Network (WAN), and the like. Some NEs (e.g., NEs 109 and 111) reside at the edge of the core infrastructure and interface with customer endpoints over various types of access networks. An NE that resides at the edge of the core infrastructure is typically implemented as an edge router, a media gateway, a border element, a firewall, a switch, and the like. An NE may also reside within the network (e.g., NEs 118-120) and may be used as a honeypot, a mail server, a router, or like device. The core network 110 also comprises an application server 112 that contains a database 115. The application server 112 may comprise any server or computer that is well known in the art, and the database 115 may be any type of electronic collection of data that is also well known in the art.

The above IP network is described to provide an illustrative environment in which packets for voice and data services are transmitted on networks. For example, packets originated and terminated by endpoint devices used for voice and data services may be transmitted via DSL access networks and core networks. When service degradation occurs, it may be detected by the network service provider or reported by a customer to the network service provider. The network service provider then dispatches maintenance personnel to perform trouble isolation and repair. However, in a large network, the cost of dispatching personnel for each detected and/or reported problem is prohibitive. Therefore, there is a need for a method that provides automatic trouble isolation for Digital Subscriber Line Access Multiplexers (DSLAM). In one embodiment, the current invention provides automatic trouble isolation of DSLAM by implementing an automated decision rule system.

Digital Subscriber Line Access Multiplexer (DSLAM) refers to a device located in a service provider's network to interact with Customer Premise Equipment (CPE) and route Digital Subscriber Line (DSL) traffic from multiple subscribers onto a single high-speed line, e.g. aggregate multiple DSL connections onto a high speed Asynchronous Transfer Mode (ATM) or Frame Relay (FR) line. For example, the low-speed side of a DSLAM connects to one or more customer premise equipment while the high-speed side interfaces with a wide area network such as an ATM or a Frame Relay network. A DSLAM also typically performs dynamic IP address assignment for customers.

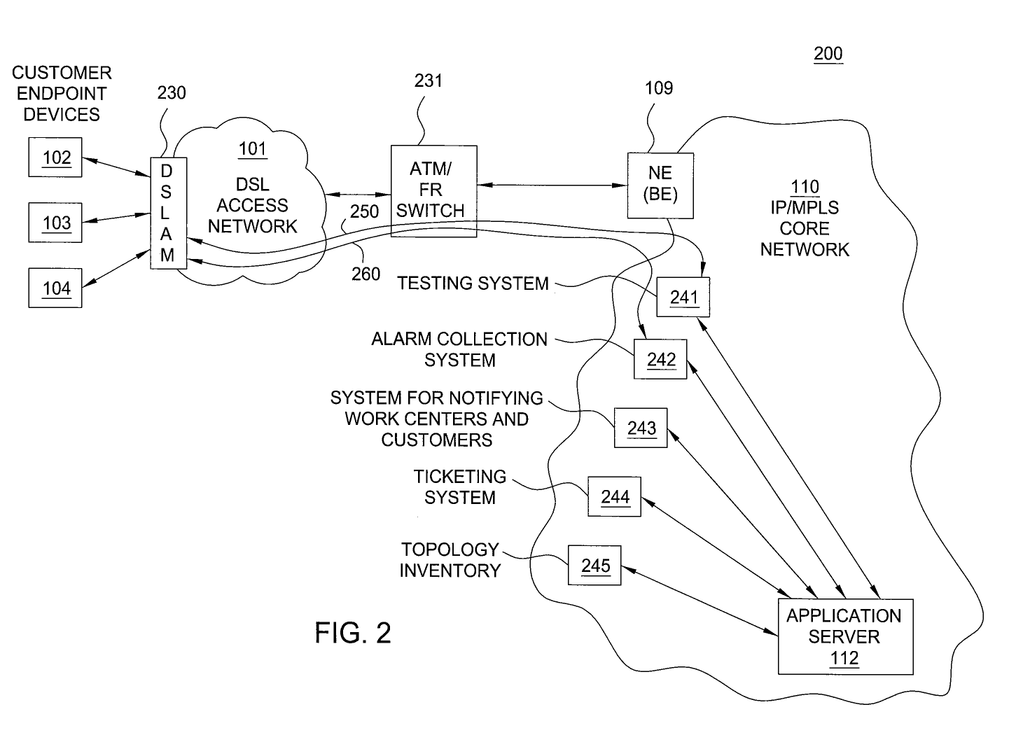

FIG. 2 illustrates an exemplary network 200 with automatic trouble isolation of DSLAM. A DSLAM 230 is placed in DSL access network 101 to interact with customer endpoint devices 102-104 and aggregate DSL traffic from subscribers using endpoint devices 102-104. The DSL access network 101 is connected to IP/MPLS core network 110 through ATM/FR switch 231 and border element 109. Packets from the DSL subscribers traverse the DSL access network 101 from the DSLAM 230 towards the ATM/FR switch 231. In one embodiment, the ATM/FR switch 231 and border element 109 for the IP/MPLS core network 110 may be collocated. In another embodiment, the border element 109 may be in another physical location. If the ATM/FR switch 231 and border element 109 are not collocated, the traffic from ATM/FR switch 231 may traverse a Layer 2 network towards another ATM/FR switch before reaching the border element 109 (e.g. traverse an ATM/FR network before reaching the border element for the IP/MPLS network). The service provider implements the current invention for providing automatic trouble isolation of DSLAM in application server 112 located in core network 110. The core network 110 also includes a testing system 241, an alarm collection system 242, system for notifying work center(s) 243, a ticketing system 244, and a topology inventory 245. The application server 112 is connected to the various systems 241-245 for automatic trouble isolation of DSLAM. The testing system 241 is connected to DSLAM 230 via path 250 for sending test packets and receiving responses. For example, the testing system may send “ping” signal. The alarm collection system 242 is connected to DSLAM 230 via path 260 to receive alarms from the DSLAM. Paths 250 and 260 may be channels established for data communication among network elements in the service provider's network or may be connections over the Internet. Ticket generation and notification systems may be made accessible by customers and/or one or more work centers.

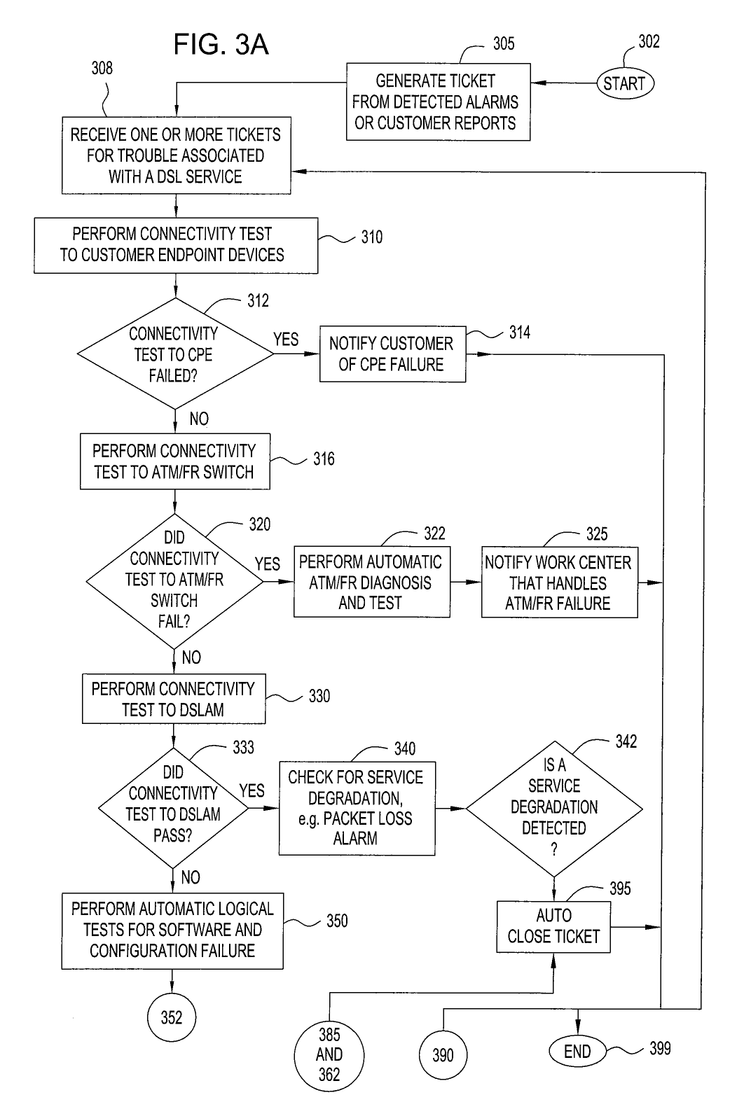

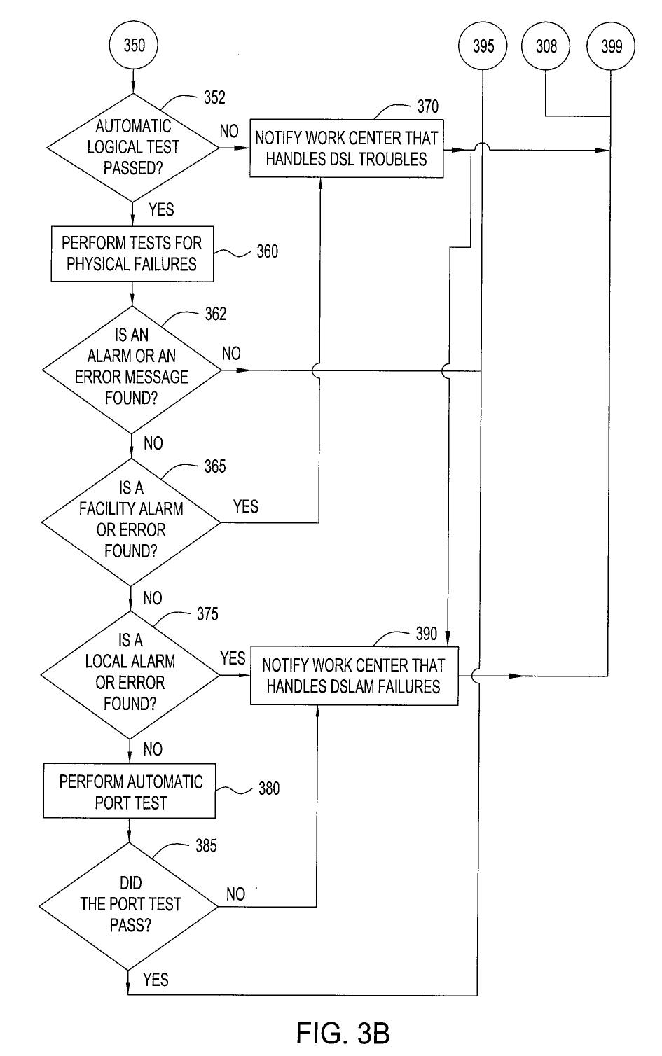

FIG. 3 illustrates a flowchart of a method 300 for automatic trouble isolation of DSLAM. Method 300 starts in step 302 and proceeds to step 305.

In step 305, method 300 generates one or more tickets for customer reported troubles or detected alarms. A ticketing system may be accessible by customers and service provider personnel. For example, a customer or work center personnel may interact with an Interactive Voice Response (IVR) system and generate a ticket. The ticket may also be created from automatically detected alarms by an alarm collection system.

In step 308, method 300 receives one or more requests/tickets for trouble associated with a DSL service. For example, a customer calls an IVR system and reports trouble on his/her DSL service.

In step 310, method 300 performs one or more connectivity tests to customer endpoint devices to determine whether or not the trouble is caused by a Customer Premise Equipment (CPE) failure. For example, the method may send “ping” signal to determine whether or not the CPE device is active. For example, the customer may have disconnected the DSL modem, and so on.

In step 312, method 300 determines whether or not the connectivity test to CPE failed. If the connectivity test to CPE failed, the method proceeds to step 314. Otherwise, the method proceeds to step 316.

In step 314, method 300 notifies the customer of the CPE failure. In one embodiment, the customer is notified automatically. In another embodiment, a customer care personnel notifies the customer. The method then proceeds to step 399 to end processing the current ticket and to step 308 to continue receiving tickets.

In step 316, method 300 performs connectivity test to ATM/FR switch attached to DSLAM to determine whether or not the trouble is caused by a network problem, e.g. Layer 2 backbone network failure.

In step 320, method 300 determines whether or not the connectivity test to ATM/FR switch failed. If the connectivity test to ATM/FR switch failed, the method proceeds to step 322. Otherwise, the method proceeds to step 330.

In step 322, method 300 performs automatic ATM/FR diagnosis and test. For example, the method may perform alarm correlation and determine the network layer (Layer 1, 2 or 3) and the appropriate work center to be notified. The method then proceeds to step 325.

In step 325, method 300 notifies the appropriate work center identified in step 322 that handles ATM/FR failures. The method then proceeds to step 399 to end processing the current ticket and to step 308 to continue receiving tickets.

In step 330, method 300 performs connectivity test to DSLAM to determine whether or not the DSLAM is active. For example, a “ping” signal may be sent by a testing system to determine whether or not the DSLAM can communicate.

In step 333, method 300 determines whether or not the connectivity test to DSLAM passed. If the connectivity test to DSLAM passed, the method proceeds to step 340 to check for service degradation. Otherwise, the method proceeds to step 350 to perform automatic logical tests for software and configuration failures.

In step 340, method 300 checks for service degradation. For example, the method may check for error messages, alarm logs, etc. to determine whether or not the service is degraded. For example, there might be packet loss exceeding a pre-determined threshold. The method then proceeds to step 342.

In step 342, method 300 determines whether or not service degradation is detected in step 340. If there is no service degradation, the method proceeds to step 395 to close the ticket. Otherwise, the method proceeds to step 350.

In step 350, method 300 performs automatic logical tests for software and configuration failures. For example, a logical test may check whether or not there is a software download problem. In another example, an IP address mismatch may be detected. For example, there may be a configuration problem due to provisioning errors, IP address mismatch, and so on.

In step 352, method 300 determines whether or not the automatic logical test passed. If the automatic logical test passed, the method proceeds to step 360 to perform tests for physical failures. Otherwise, the method proceeds to step 370 to notify the work center handling DSL troubles.

In step 360, method 300 performs tests for physical failures. For example, the method may retrieve alarm and error messages for physical failures. The method may search for facility alarms such as Layer 1 alarms, port alarms for the DSLAM, and local alarms (e.g. environmental alarms, congestion/utilization alarms, performance alarms for packet/cell loss, and so on). The method then proceeds to step 362.

In step 362, method 300 determines whether or not an alarm or an error message is found. If no alarm/error message is found, the method proceeds to step 395 to close the ticket. Otherwise, the method proceeds to step 365.

In step 365, method 300 determines whether or not a facility alarm or error is found. For example, a Layer 1 alarm may be found. If a facility alarm (OC-3, OC-12, DS1, DS3, etc.) is found, the method proceeds to step 370 to notify the work center handling DSL failures. Otherwise, the method proceeds to step 375.

In step 370, method 300 notifies the work center handling DSL problems. In one embodiment, a work center that handles customer oriented DSL problems may be provided. In another example, the diagnosis of a test may be provided to a work center that handles all tickets. The method then proceeds to step 399 to end processing the current ticket and to step 308 to continue receiving tickets.

In step 375, method 300 determines whether or not a local alarm is found. For example, the method may check for environmental alarms, congestion/utilization alarms, performance alarms for packet/cell loss, and so on. If a local alarm is found, the method proceeds to step 390 to notify work center handling DSLAM failures. Otherwise, the method proceeds to step 380.

In step 380, method 300 performs automatic port test. For example, the method attempts to reset the port in case it is taken out of service in error. The method then proceeds to step 385.

In step 385, method 300 determines whether or not the port test passed. If the port test passed (i.e. port is operating properly), the method proceeds to step 395 to close the ticket. Otherwise, the method proceeds to step 390.

In step 390, method 300 notifies work center handling DSLAM failures. The trouble is isolated at being DSLAM related and thus remedy may be performed by the appropriate personnel/work center. The method then proceeds to step 399 to end processing the current ticket and to step 308 to continue receiving tickets.

In step 395, method 300 closes the ticket. The method proceeds to steps 399 to end processing the current ticket and to step 308 to continue receiving tickets. Method 300 ends in step 399.

Those skilled in the art would realize the partitioning of tasks in work centers is provided as an exemplary implementation. In addition, the various systems for ticketing, alarm collection, alarm/ticket correlation, connectivity tests, automatic logical tests, physical failure tests, topology inventory, port tests, etc. may be in separate or the same device (server). As such, the above exemplary embodiment is not intended to limit the invention or the implementation.

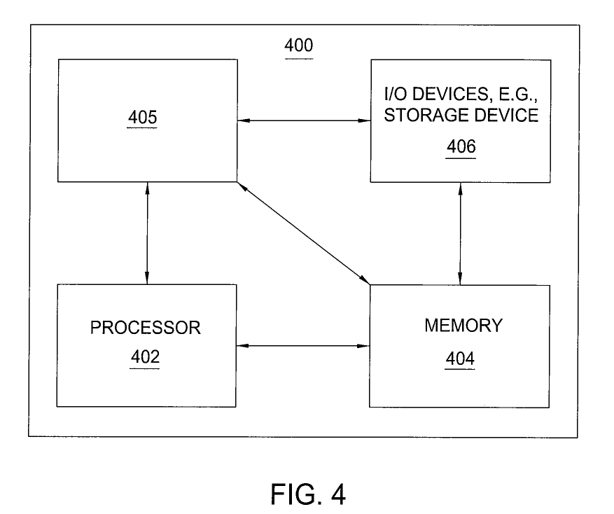

FIG. 4 depicts a high-level block diagram of a general-purpose computer suitable for use in performing the functions described herein. As depicted in FIG. 4, the system 400 comprises a processor element 402 (e.g., a CPU), a memory 404, e.g., random access memory (RAM) and/or read only memory (ROM), a module 405 for trouble isolation of DSLAM, and various input/output devices 406 (e.g., storage devices, including but not limited to, a tape drive, a floppy drive, a hard disk drive or a compact disk drive, a receiver, a transmitter, a speaker, a display, a speech synthesizer, an output port, and a user input device (such as a keyboard, a keypad, a mouse, and the like)).

It should be noted that the present invention can be implemented in software and/or in a combination of software and hardware, e.g., using application specific integrated circuits (ASIC), a general purpose computer or any other hardware equivalents. In one embodiment, the present module or process 405 for trouble isolation of DSLAM can be loaded into memory 404 and executed by processor 402 to implement the functions as discussed above. As such, the present method 405 for trouble isolation of DSLAM (including associated data structures) of the present invention can be stored on a computer readable medium or carrier, e.g., RAM memory, magnetic or optical drive or diskette and the like.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

What is claimed is:

1. A method for trouble isolation of DSLAM, comprising:
receiving a request or a ticket for trouble isolation associated with a Digital Subscriber Line (DSL) service;
performing connectivity test to customer premise equipment to differentiate between failures in customer premise versus network;
performing connectivity test to an ATM or FR switch to differentiate between failures in DSLAM versus ATM/FR switch network;
performing connectivity test to Digital Subscriber Line Access Multiplexer (DSLAM);
isolating software and configuration failures of DSLAM by performing one or more logical tests; and
isolating physical failure of DSLAM by performing one or more test for physical failures.

2. A computer-readable medium having stored thereon a plurality of instructions, the plurality of instructions including instructions which, when executed by a processor, cause the processor to perform the steps of a method for trouble isolation of DSLAM, comprising:
receiving a request or a ticket for trouble isolation associated with a Digital Subscriber Line (DSL) service;
performing connectivity test to customer premise equipment to differentiate between failures in customer premise versus network;
performing connectivity test to an ATM or FR switch to differentiate between failures in DSLAM versus ATM/FR switch network;
performing connectivity test to Digital Subscriber Line Access Multiplexer (DSLAM);
isolating software and configuration failures of DSLAM by performing one or more logical tests; and
isolating physical failure of DSLAM by performing one or more test for physical failures.

3. An apparatus for trouble isolation of DSLAM, comprising:
means for receiving a request or a ticket for trouble isolation associated with a Digital Subscriber Line (DSL) service;
means for performing connectivity test to customer premise equipment to differentiate between failures in customer premise versus network;
means for performing connectivity test to an ATM or FR switch to differentiate between failures in DSLAM versus ATM/FR switch network;
means for performing connectivity test to Digital Subscriber Line Access Multiplexer (DSLAM);
means for isolating software and configuration failures of DSLAM by performing one or more logical tests; and
means for isolating physical failure of DSLAM by performing one or more test for physical failures.
